(19) United States
(12) Patent Application Publication
(10) Pub. No.: US 2016/0227648 A1
(43) Pub. Date: Aug. 4, 2016

(54) PRINTED WIRING BOARD CAPABLE OF SUPPRESSING MOUNTING FAILURE OF SURFACE MOUNT DEVICE FOR FLOW SOLDERING

(71) Applicant: FANUC Corporation, Yamanashi (JP)

(72) Inventors: Takeshi SAWADA, Yamanashi (JP); Yuichi OKOUCHI, Yamanashi (JP); Daisuke MIURA, Yamanashi (JP)

(21) Appl. No.: 15/013,286

(22) Filed: Feb. 2, 2016

(30) Foreign Application Priority Data
Feb. 3, 2015 (JP) 2015-19698

(51) Int. Cl. H05K 1/11; H05K 1/02; H05K 1/18

(52) U.S. Cl. CPC H05K 1/112; H05K 1/181; H05K 1/0271

(57) ABSTRACT

The width of a lead-terminal connection pad on a printed wiring board is not greater than the width of a lead terminal. Therefore, a wider space can be secured between adjacent solder joints, so that bridge failure can be suppressed. Further, the length of projection of the lead-terminal connection pad at the proximal portion of the lead terminal is shorter than that of a lead-terminal connection pad on a conventional printed wiring board. Thus, a solder pool at the proximal portion of the lead terminal can be reduced to suppress bridge defect.

### BACKGROUND OF THE INVENTION

1. Field of the Invention

The present invention relates to a printed wiring board capable of suppressing mounting failure, such as a short circuit, by means of adjacent lead terminals or lead-terminal connection pads of a surface mount device in a flow soldering step.

2. Description of the Related Art

FIGS. 7 to 9 show an example of the configuration of a conventional printed wiring board. FIG. 7 illustrates a surface mount device 14 mounted on a printed wiring board 10, lead terminals 13, and lead-terminal connection pads 11. FIG. 7 shows a part of a package body of the surface mount device 14. FIG. 8 is a sectional view of one of the lead terminals 13 of FIG. 7 taken in its extending direction. A top fillet 15 is formed on a front pad projection portion of the lead. A large back fillet 16 is formed on the rear portion of the lead. Further, FIG. 9 is a sectional view of one of the lead terminals 13 of FIG. 7 taken in a direction perpendicular to the extending direction. The lead-terminal connection pad 11 is made wider than the lead terminal 13 to form a side fillet 17.

A process for mounting the surface mount device 14 on the printed wiring board 10 roughly comprises steps of reflow soldering and flow soldering. In the reflow soldering, the amount of solder can be adjusted by adjusting the supply of a solder paste. In the flow soldering, in contrast, the printed wiring board 10 is soldered by being brought into contact with jet solder in a molten solder bath, so that it is difficult to accurately adjust the solder supply to the surface mount device 14. Therefore, the process for mounting the surface mount device 14 on the printed wiring board 10 by the flow soldering has a problem that a short circuit is caused between the adjoining lead terminal 13 and lead-terminal connection pad by the surface tension of the solder.

Conventionally, therefore, there are techniques in which a solder-free partition plate is formed in a gap in each lead-terminal connection pad 11 of the surface mount device 14 so as to suppress bridge failure between each lead terminal 13 and the pad 11 (Japanese Patent Applications Laid-Open Nos. 9-219487 and 5-259624).

Further, there are techniques in which bridge failure at the proximal portion of the lead terminal is suppressed by tapering the lead-terminal connection pad 11 for soldering the lead terminal 13 of the surface mount device 14 toward the proximal portion of the lead terminal (or toward the package of the surface mount device 14) so that the pad 11 is as wide as the lead terminal 13 (Japanese Patent Applications Laid-Open Nos. 2001-339146 and 3-229486).

### SUMMARY OF THE INVENTION

The techniques disclosed in Patent Document 1 (Japanese Patent Application Laid-Open No. 9-219487) and Patent Document 2 (Japanese Patent Application Laid-Open No. 5-259624) are disadvantageous in that the use of the partition plate results in an increase in cost and the need of additional processes. In the techniques disclosed in Patent Document 3 (Japanese Patent Application Laid-Open No. 2001-339146) and Patent Document 4 (Japanese Patent Application Laid-Open No. 3-229486), bridge failure is suppressed by inhibiting the concentration of molten solder on curved portions by a capillary phenomenon in the reflow soldering step. In the flow soldering step, however, soldering is performed by bringing the printed wiring board into contact with the jet solder. The wider each lead-terminal connection pad, therefore, the shorter the spaces between the connection pads corresponding to the distal end portions of the lead terminals are. Thus, there is a possibility of the occurrence of bridge failure, so that a satisfactory effect cannot be expected.

Accordingly, in view of the above-described problems of the prior art, the object of the present invention is to provide a printed wiring board capable of suppressing mounting failure of a surface mount device in a flow soldering step.

A printed wiring board according to the present invention, on which a surface mount device with a plurality of lead terminals is mounted by flow soldering, comprises a plurality of lead-terminal connection pads for mounting the surface mount device, the distance between each two adjacent ones of the lead terminals being not greater than the distance between each two adjacent ones of the lead-terminal connection pads.

Each of the lead-terminal connection pads is formed of a front pad projection portion located in front of the lead, a pad center portion located below the lead, and a rear pad projection portion located at the back of the lead, the front pad projection portion being longer than the rear pad projection portion.

Each of the lead-terminal connection pads is formed of a front pad projection portion located in front of the lead and a pad center portion located below the lead.

The printed wiring board and the reverse side of a package of the surface mount device are bonded together by adhesive means.

The printed wiring board and bottom surface ends and side surfaces of a package of a contour portion without a lead terminal in the surface mount device are bonded together by adhesive means.

According to the present invention, there can be provided a printed wiring board capable of suppressing mounting failure of a surface mount device in a flow soldering step.

### BRIEF DESCRIPTION OF THE DRAWINGS

The above and other objects and features of the present invention will be obvious from the ensuing description of embodiments with reference to the accompanying drawings, in which:

FIGS. 1A, 1B and 1C are views showing Embodiment 1 according to the present invention;

FIG. 2 is a view illustrating Embodiment 1 according to the present invention;

FIG. 3 is a view showing Embodiment 2 according to the present invention;

FIG. 4 is a view showing Embodiment 3 according to the present invention;

FIG. 5 is a view showing Embodiment 4 according to the present invention;

FIG. 6 is a view showing Embodiment 5 according to the present invention;

FIG. 7 is a view showing a conventional printed wiring board;

FIG. 8 is a sectional view of a lead terminal of a mounted component mounted on the conventional printed wiring board; and

FIG. 9 is a sectional view of the lead terminal of the mounted component mounted on the conventional printed wiring board.

### DETAILED DESCRIPTION OF THE PREFERRED EMBODIMENTS

Embodiments of the present invention will now be described with reference to the accompanying drawings.

### Embodiment 1

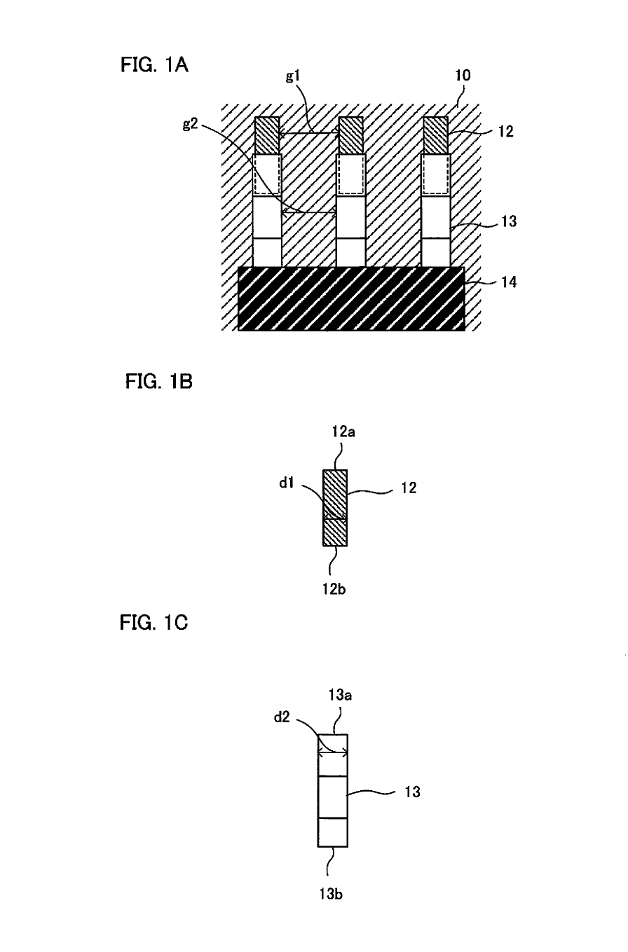

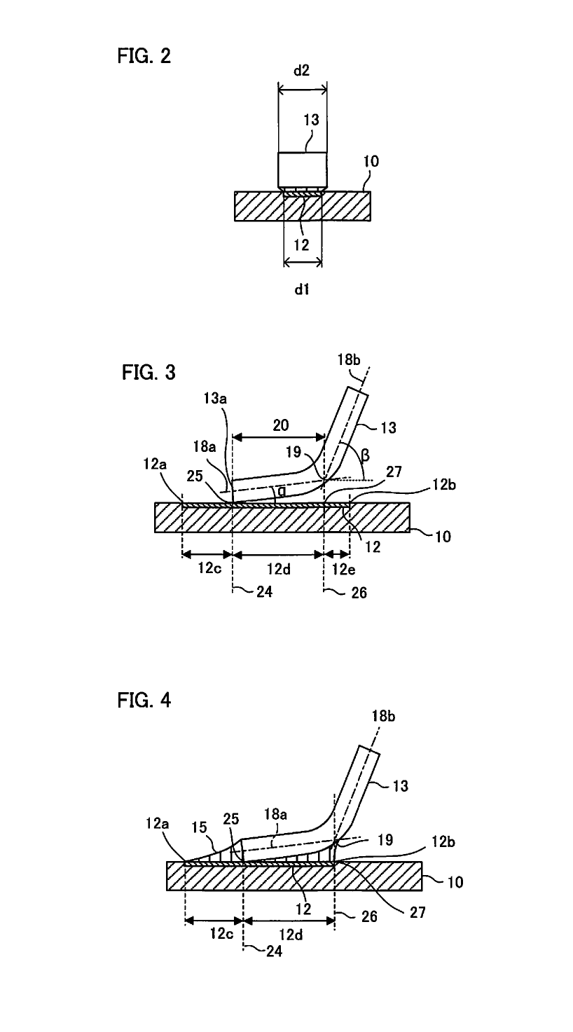

FIGS. 1A, 1B and 1C are schematic views showing a configuration of the present embodiment. FIG. 2 is a front view of a lead terminal briefly showing the present embodiment. A surface mount device 14 is mounted on a printed wiring board 10 in a flow soldering step. The printed wiring board 10 is provided with lead-terminal connection pads 12 for soldering lead terminals 13 of the surface mount device 14.

Each of the lead-terminal connection pads 12, which is provided on the printed wiring board 10 so as to be electrically connected to a circuit pattern (not shown), has a rectangular shape with a width kept constant from an outer end portion 12a to an inner end portion 12b. The direction from the outer end portion 12a toward the inner end portion 12b is the direction in which the package of the surface mount device 14 is approached as the surface mount device 14 is mounted on the printed wiring board 10. The width of each lead-terminal connection pad 12 is denoted by d1. The surface mount device 14 is provided with the lead terminals 13 and the width (denoted by d2) of each lead terminal 13 is kept constant from a distal end portion 13a to a proximal portion 13b. The proximal portion 13b is a part of the lead terminal 13 projecting outward from the package of the surface mount device 14. The width of that part of the lead terminal 13 which is connected to the lead-terminal connection pad 12 by soldering is at least equal to the width d2.

The width dl of the lead-terminal connection pad 12 is not larger than the width d2 of the lead terminal 13 (d1≦d2). In order to suppress mounting failure in the flow soldering step, a gap in the lead-terminal connection pad or the lead terminal can be maximized by making the width of the lead-terminal connection pad not larger than that of the lead terminal.

In other words, there is a relation g1≧g2, where g1 is the distance between each two adjacent lead-terminal connection pads 12 of the printed wiring board 10 and g2 is the distance between each two adjacent lead terminals 13 of the surface mount device 14. Thus, the width of a gap between adjoining solder joints (respective joints of the lead-terminal connection pad 12 and the lead terminal 13) can be increased to suppress bridge failure.

### Embodiment 2

FIG. 3 is a sectional view of a lead terminal briefly showing a lead length according to the present embodiment. In general, when a surface mount device 14 is mounted on a printed wiring board 10, a lead terminal 13 rises at an angle α from its distal end portion 13a, further rises at an angle β (α<β) from a lead curve portion 19, and then reaches a package of the surface mount device 14. The angles α and β are based on a surface of a lead-terminal connection pad 12 as a reference surface.

The point of intersection of a thickness center line 18a of a front portion of the lead terminal 13, ranging from the distal end portion 13a to the lead curve portion 19, and a thickness center line 18b of a rear portion behind the lead curve portion 19 corresponds to the lead curve portion 19. Numeral 25 denotes the point of intersection of the lead-terminal connection pad 12 and a perpendicular line 24 drawn down from the distal end portion 13a to the lead-terminal connection pad 12.

Further, numeral 27 denotes the point of intersection of the lead-terminal connection pad 12 and a perpendicular line 26 drawn down from the lead curve portion 19 to the lead-terminal connection pad 12.

The lead-terminal connection pad 12 can be divided between a front pad projection portion 12c, pad center portion 12d, and rear pad projection portion 12e. The front pad projection portion 12c is located in front of the lead and covers a section from the outer end portion 12a to the intersection point 25. The pad center portion 12d is located below the lead and covers a section from the intersection point 25 to the intersection point 27. The rear pad projection portion 12e is located at the back of the lead and covers a section from the intersection point 27 to the inner end portion 12b. The length of the pad center portion 12d below the lead is called a lead length 20. The length of projection of the lead-terminal connection pad 12 from the distal end portion 13a (or the length of the front pad projection portion 12c in front of the lead) is characterized in being longer than the length of the rear pad projection portion 12e at the back of the lead.

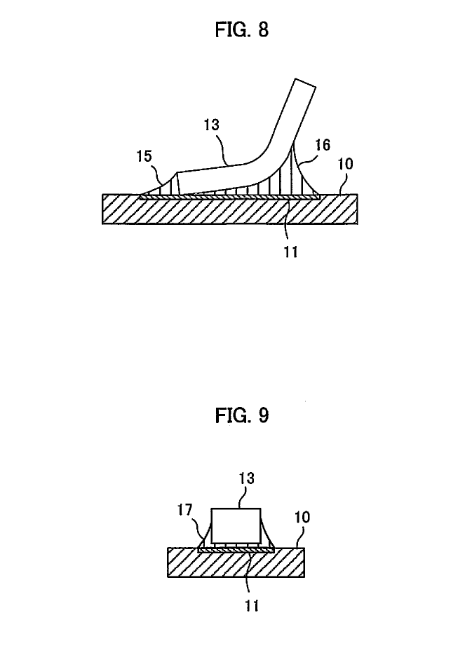

Further, the length of projection of the lead-terminal connection pad 12 at the proximal portion of the lead terminal (or the length of the rear pad projection portion 12e at the back of the lead) is shorter than that of the lead-terminal connection pad 11 (see FIGS. 7 to 9) on the conventional printed wiring board. Thus, in the printed wiring board 10 of Embodiment 1, a solder pool at the proximal portion of the lead terminal can be reduced to suppress bridge failure.

### Embodiment 3

The present embodiment shown in FIG. 4 is characterized in that the length of a projection portion 12e of a lead-terminal connection pad 12 from an end of its portion at the back of a lead terminal is 0 and that an inner end portion 12b of a lead-terminal connection pad 12 is coincident with a point 27 of intersection of the lead-terminal connection pad 12 and a perpendicular line 26 drawn down from the lead curve portion 19 of FIG. 3 to the lead-terminal connection pad 12. Specifically, the lead-terminal connection pad 12 is formed of a front pad projection portion 12c, which is located in front of the lead and covers a section from an outer end portion 12a to an intersection point 25, and a pad center portion 12d, which is located below the lead and covers a section from the intersection point 25 to the intersection point 27. Thus, in a printed wiring board 10 of Embodiment 3, a solder pool at the proximal portion of the lead terminal can be reduced to suppress bridge failure.

### Embodiment 4

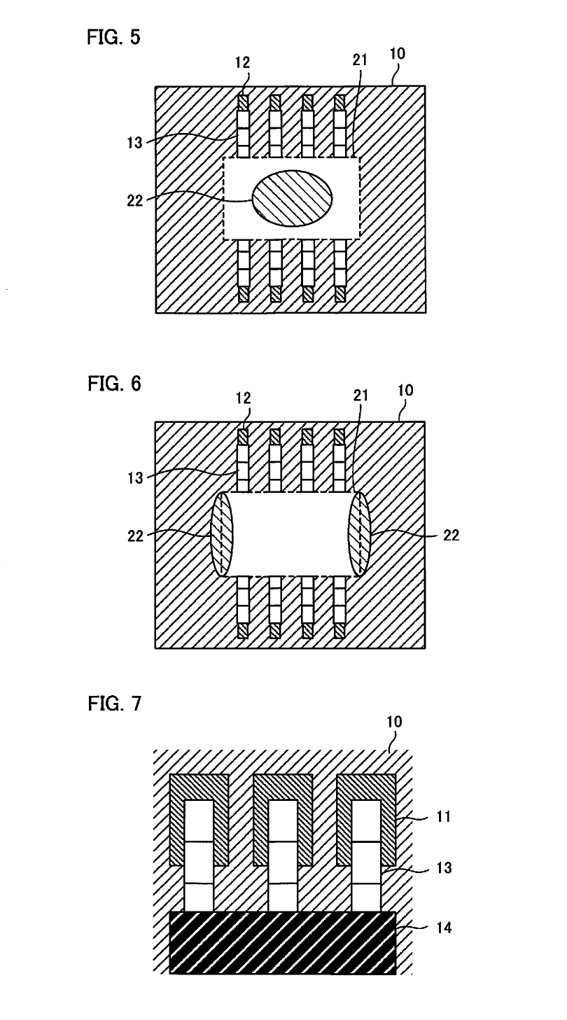

FIG. 5 is a general top view briefly showing the present embodiment. FIG. 5 shows how an adhesive is applied between a printed wiring board 10 and the bottom surface of a package of a surface mount device 14 for flow soldering. This configuration is characterized in that good mechanical strength can be achieved even in case the amount of solder used for soldering is small. A double-sided tape may be used in place of the adhesive. A member such as the adhesive or the double-sided tape used to bond two members is called an adhesive member.

### Embodiment 5

FIG. 6 is a general top view briefly showing the present embodiment. In FIG. 6, the entire body of surface mount device 21 is illustrated. An adhesive is applied between a printed wiring board and the bottom surface ends and side surfaces of a package of a contour portion (adhesive application area 22) without a lead terminal in a surface mount device for flow soldering. Thus, good mechanical strength can be achieved even in case the amount of solder used for soldering is small.

1. A printed wiring board on which a surface mount device with a plurality of lead terminals is mounted by flow soldering, the printed wiring board comprising:
a plurality of lead-terminal connection pads for mounting the surface mount device,
wherein the distance between each two adjacent ones of the lead terminals is not greater than the distance between each two adjacent ones of the lead-terminal connection pads.

2. The printed wiring board according to claim 1, wherein each of the lead-terminal connection pads is formed of a front pad projection portion located in front of the lead, a pad center portion located below the lead, and a rear pad projection portion located at the back of the lead, the front pad projection portion being longer than the rear pad projection portion.

3. The printed wiring board according to claim 1, wherein each of the lead-terminal connection pads is formed of a front pad projection portion located in front of the lead and a pad center portion located below the lead.

4. The printed wiring board according to claim 1, wherein the printed wiring board and the reverse side of a package of the surface mount device are bonded together by adhesive means.

5. The printed wiring board according to claim 1, wherein the printed wiring board and bottom surface ends and side surfaces of a package of a contour portion without a lead terminal in the surface mount device are bonded together by adhesive means.
